(19) United States
(12) Patent Application Publication
(10) Pub. No.: US 2012/0256703 A1
(43) Pub. Date: Oct. 11, 2012

(54) BANDPASS FILTER AND ELECTRONIC DEVICE

(75) Inventors: Ju Yeon HONG, Daejeon-si (KR); Jae Ick CHOI, Daejeon-si (KR); Sungtek KAHNG, Seoul (KR); Geonho JANG, Incheon-si (KR); Boram LEE, Chungcheongnam-do (KR); Jaehoon CHOI, Seoul (KR)

(73) Assignees: IUCF-HYU ( Industry-University Cooperation Foundation Hanyang University, Seoul (KR); Electronics and Telecommunications Research Institute, Daejeon-si (KR)

(21) Appl. No.: 13/304,508

(22) Filed: Nov. 25, 2011

(30) Foreign Application Priority Data
Apr. 8, 2011 (KR) 10-2011-0032437

(51) Int. Cl. H03H 7/065

(52) U.S. Cl. 333/168

(57) ABSTRACT

A bandpass filter includes resonator coupling line on which a plurality of composite right/left-handed (CRLH) resonators are disposed. The plurality of CRLH resonators are inductively coupled with each other. The design variables can be increased through inductive coupling in the resonance period. Also, the skirt characteristics and the isolation can be improved.

### CROSS-REFERENCE TO RELATED APPLICATIONS

This application claims the benefit of priority of Korean Patent Application No. 10-2011-0032437 on Apr. 8, 2011, all of which is incorporated by reference in its entirety herein.

### BACKGROUND OF THE INVENTION

1. Field of the Invention

The present invention relates to a bandpass filter, and more particularly, to a bandpass filter having a composite right/left-handed (CRLH) structure and an electronic device using the same.

2. Related Art

A bandpass filter is an essential factor in an electronic system such as a wireless communication system. With the development of a wireless communication system, a demand for a small, multi-functional, and an inexpensive bandpass filter has also been increased.

The bandpass filter needs to have low insertion/return loss, and high frequency selectivity. However, it is difficult to miniaturize equipment because of a long wavelength due to a low frequency in an ultra high frequency (UHF) band of a range of 880 MHz to 960 MHz

In order to obtain better characteristics, a composite right/left handed (CRLH) structure has been introduced into the bandpass filter. As known well, a left-handed propagation rule configures a left-handed propagation triplet by an electrical field vector, a magnetic field vector, and a propagation vector and a right-handed propagation rule configures a right-handed propagation triplet by an electromagnetic vector, a magnetic vector, and a propagation vector.

FIG. 1 shows an example of the bandpass filter according to the related art. This may refer to U.S. Pat. No. 7,619,495 B2.

Sub-drawing (A) represents the bandpass filter and Sub-drawing (B) represents a single unit cell.

The bandpass filter is configured by a plurality of unit cells 1. The unit cell 1 includes a conductor strip 2 and a ground plane. The ground plate includes a first splint ring 6 and a second split ring 7. The first split ring 6 and the second split ring 7 provide a split-rings resonator (SRR) structure.

The conductor strip 2 is shortened by a gap 3 and a metallic stub 4 is disposed in the gap 3. The gap 3 is used as a capacitance element. The metallic stub 4 is connected to vias 41 connected to the ground plane.

FIG. 2 shows another example of the bandpass filter according to the related art. This may refer to “Characteristics of the Composite Right/Left-Handed Transmission Lines”, A. Sanada, C. Caloz, and T. Itoh in IEEE Microwave and Wireless Components Letters, Vol. 14, No. 2, February 2004. This represents a one-dimensional CRLH transmission line formed in a microstrip line.

A unit cell 20 includes an interdigital capacitor and a shortened stub.

The CRLH transmission line is a transmission line configured by periodic repetition of the unit cell. The unit cell is configured by a series capacitor and a shunt inductor as well as a series inductor and a shunt capacitor.

According to the conventional CRLH structure, a degree of freedom in a design of the bandpass filter is limited and it is difficult to control isolation and barrier characteristics.

### SUMMARY OF THE INVENTION

The present invention provides a bandpass filter using an inductive coupling structure of a CRLH resonator.

The present invention also provides a CRLH resonator based bandpass filter generating a transmission zero.

In an aspect, a bandpass filter includes a resonator coupling line on which a plurality of composite right/left-handed (CRLH) resonators are disposed, wherein the plurality of CRLH resonators are inductively coupled with each other.

Each of the plurality of CRLH resonators may include a first interdigital line connected to an input port in series, a second interdigital line connected to an output port in series, a connection line connecting the first interdigital line to the second interdigital line, and an inductor line connected to the connection line in parallel and having a shortened end.

Each of the first interdigital line and the second interdigital line may include a pair of parallel lines facing each other, having a gap disposed therebetween.

The connection line may be a T-junction type including a serial inductor and a parallel capacitor.

The connection line may be an element of a right-handed propagation rule generating a phase delay and the first interdigital line, the second interdigital line, and the inductor line are elements of a left-handed propagation rule generating a phase lead.

A total phase of the phase delay and the phase lead may be substantially 0.

A phase of the element of the right-handed propagation rule and a phase of the element of the left-handed propagation rule may be opposite to each other.

The phase of the element of the right-handed propagation rule and the phase of the element of the left-handed propagation rule may have a difference of 180°.

The bandpass filter having the frequency selectivity is provided. In addition, The process costs can be saved and the products can be miniaturized.

Further, the design variables can be increased through inductive coupling in the resonance period. Also, the skirt characteristics and the isolation can be improved.

### BRIEF DESCRIPTION OF THE DRAWINGS

FIG. 1 shows an example of the bandpass filter according to the related art.

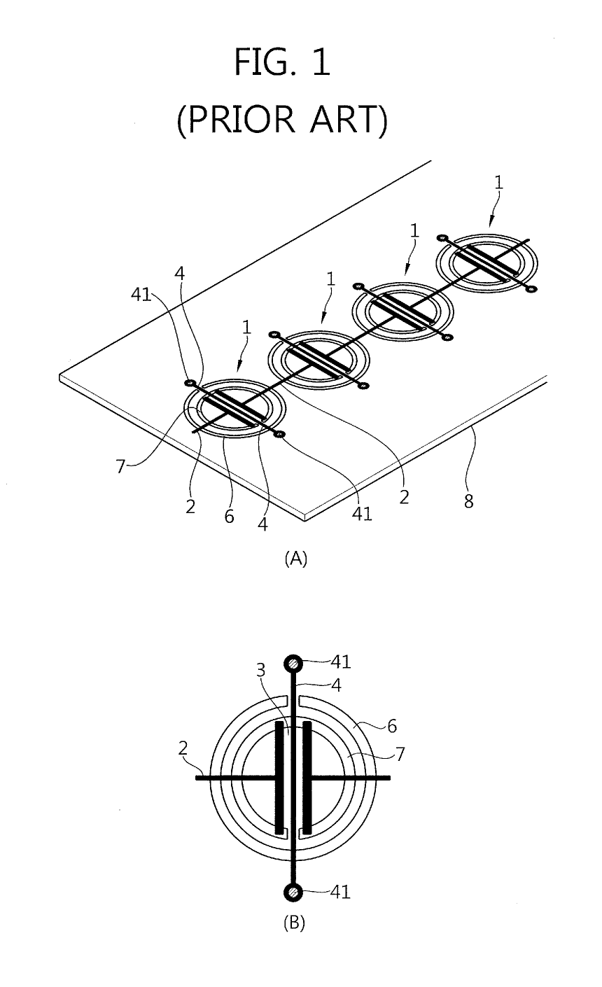

FIG. 2 shows another example of the bandpass filter according to the related art.

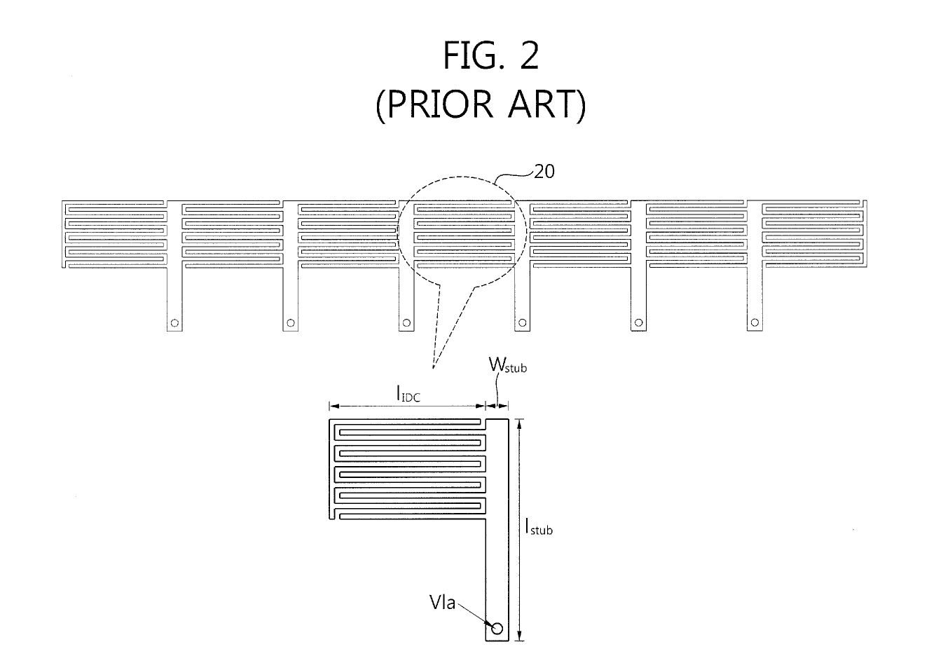

FIG. 3 shows a circuit model of a T-type CRLH resonator.

FIG. 4 shows a circuit model of a pi-type CRLH resonator.

FIG. 5 shows a bandpass filter according to an exemplary embodiment of the present invention.

FIG. 6 is a diagram showing a configuration of a CRLH resonator according to an exemplary embodiment of the present invention.

FIG. 7 is a diagram showing a physical structure of the CRLH resonator of FIG. 6.

FIG. 8 is a graph showing simulation results for a frequency response of the resonator of FIG. 6.

FIG. 9 is a graph showing narrowband frequency response characteristics of the proposed bandpass filter.

FIG. 10 is a graph showing broadband frequency response characteristics of the proposed bandpass filter.

FIG. 11 is a graph showing narrowband frequency response characteristics of the existing bandpass filter.

FIG. 12 is a graph showing broadband frequency response characteristics of the existing bandpass filter.

FIG. 13 is a diagram showing a configuration of the bandpass filter according to the exemplary embodiment of the present invention.

FIG. 14 is a graph showing a frequency response of the existing Chebyshev 9th order bandpass filter.

FIG. 15 is a graph showing a frequency response when a transmission zero is present in the existing Chebyshev 9th order bandpass filter.

FIG. 16 is a graph showing the frequency response of the proposed bandpass filter.

FIG. 17 is a conceptual diagram showing a coupling between resonators of the proposed bandpass filter.

FIG. 18 is an equivalent circuit of the coupling of non-adjacent resonators by a transmission zero.

FIG. 19 is a graph showing a frequency at which the transmission zero is generated by an admittance parameter.

FIG. 20 is a metamaterial structure based UHF bandpass filter according to an embodiment of the present invention.

FIG. 21 is a diagram showing three-dimensional electromagnetic simulation results of the bandpass filter according to the exemplary embodiment of the present invention.

FIG. 22 is a diagram showing three-dimensional electromagnetic simulation results of the bandpass filter according to the exemplary embodiment of the present invention.

### DESCRIPTION OF EXEMPLARY EMBODIMENTS

The proposed bandwidth filter is based on a composite right/left-handed (CRLH) resonator rather than the existing half-wavelength resonator so as to reduce a volume.

A passband of the proposed bandpass filter may be an ultra high frequency (UHF) in a range of 880 MHz to 960 MHz. However, this is only an example and the passband may be a band higher and lower than the UHF band.

The proposed bandpass filter considers inter-band isolation. The bandpass filter generates a transmission zero after an upper side and a lower side of the passband to improve skirt characteristics.

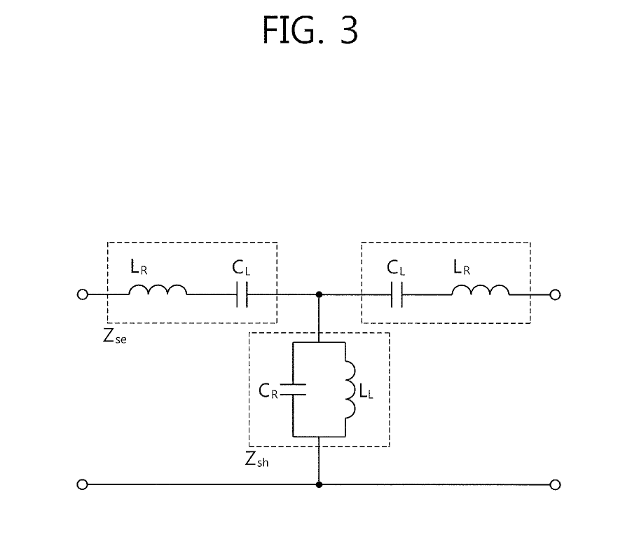

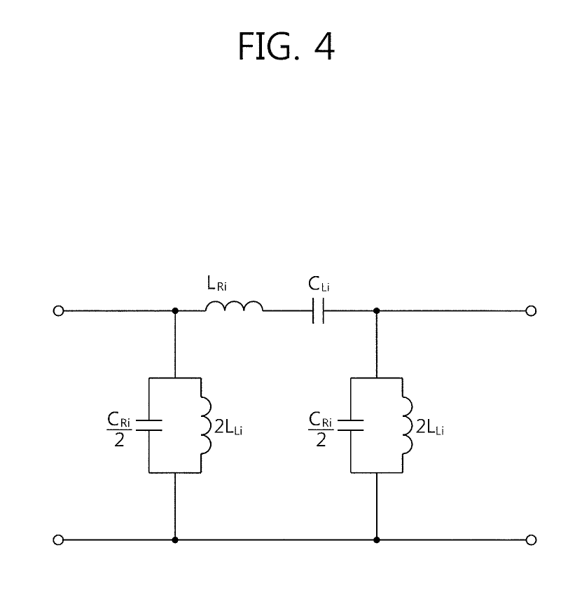

FIG. 3 shows a circuit model of a T-type CRLH resonator. FIG. 4 shows a circuit model of a pi-type CRLH resonator. FIGS. 3 and 4 both have the CRLH structure in which the right-handed propagation rule and the left-handed propagation rule are coupled with each other, except that the arrangement of the capacitor and the inductor are different from each other.

A serial inductor and a parallel inductor are elements of the right-handed propagation rule generating a phase delay and the serial capacitor and the parallel inductor are elements of the left-handed propagation rule generating a phase lead.

A right-handed propagation rule on the microstrip line is a phenomenon often observed in nature and corresponds to the low pass characteristics of the bandpass filter since the propagation energy and the moving direction of the phase have the same phase.

The left-handed propagation rule is implemented by a pair of serial capacitor and parallel inductor. The propagation energy and the moving direction of the phase have an opposite phase.

Therefore, when the elements of the right-handed propagation rule and the elements of the left-handed propagation rule are disposed on the microstrip line, the phase delay generated on the transmission line of the right-handed propagation rule may be offset with the phase lead by the left-handed propagation rule.

That is, the resonance frequency of the elements of the right-handed propagation rule and the resonance frequency of the elements of the left-handed propagation rule equally coincide with the center of the UHF band or the ISM band. This satisfies a balanced condition. Although a frequency is present, the phase and the propagation constant is 0, such that a zero-th order resonance (ZOR) phenomenon generating resonance regardless of the wavelength occurs.

In this case, since the resonance condition does not depend on the size of the resonator, the size of the bandpass filter may be 0.25 λ or less. In addition, the bandwidth may be maintained by disposing a long parallel line so that the adjacent resonators may be coupled.

Therefore, the bandpass filter according to the related art has an integer multiple of 0.5 λ as a basic resonant length and uses the plurality of resonators and thus, exceed a size of 2 λ. However, the proposed bandpass filter uses the CRLH structure to reduce the size thereof to about ⅛ as compared with the bandpass filter according to the related art.

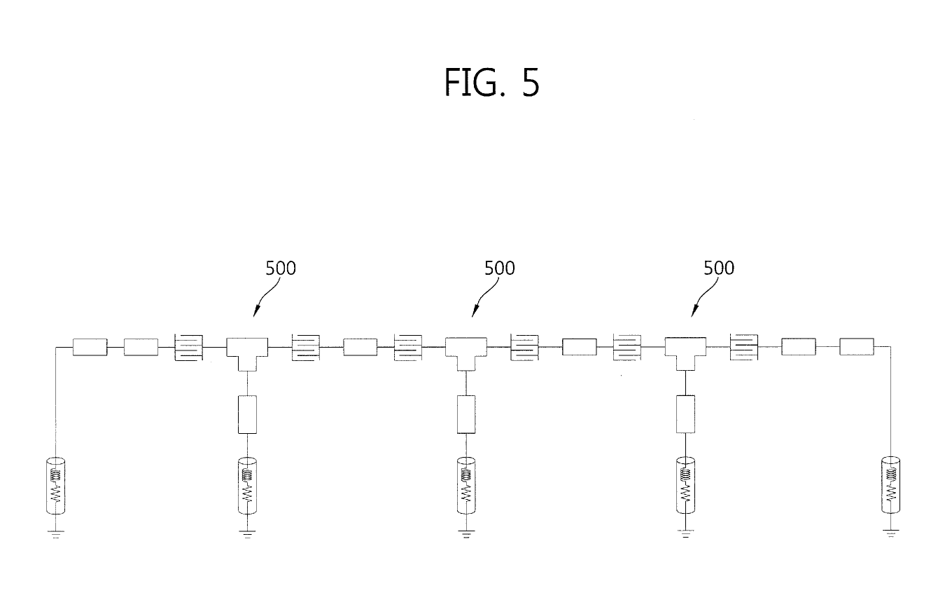

FIG. 5 shows a bandpass filter according to an exemplary embodiment of the present invention.

The bandpass filter includes a plurality of CRLH resonator 500. The circuit model of each CRLH resonator 500 may be an example of FIGS. 3 and/or 4.

Each CRLH resonator 500 may be connected by an inductive coupling structure.

The metamaterial characteristics having the CRLI-I structure are allocated to the resonator and the CRLH resonance characteristics of the original resonator are changed when coupling the resonators to each other.

The proposed exemplary embodiment of the present invention forms the passband band and the barrier band while maintaining each metamaterial characteristics of each resonator even in the case in which the the coupling is used.

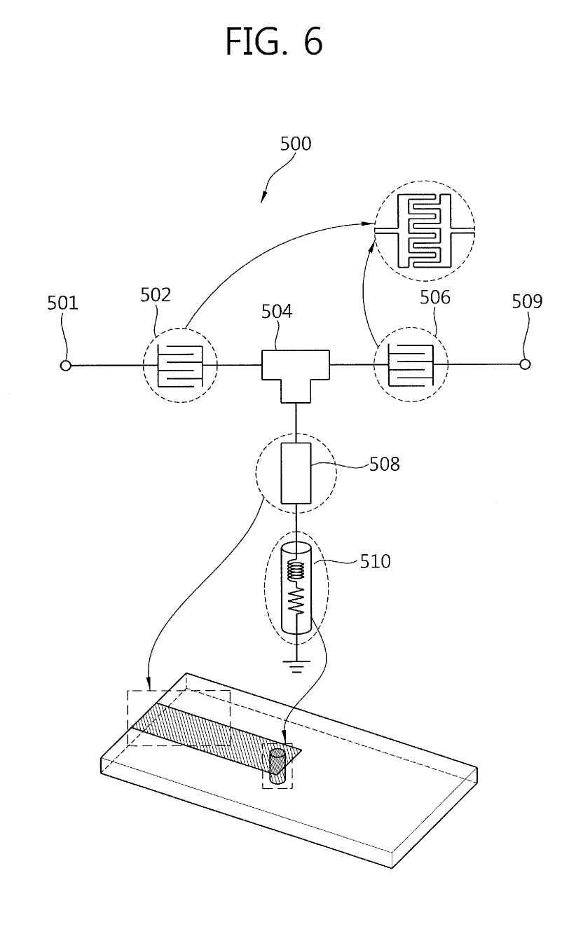

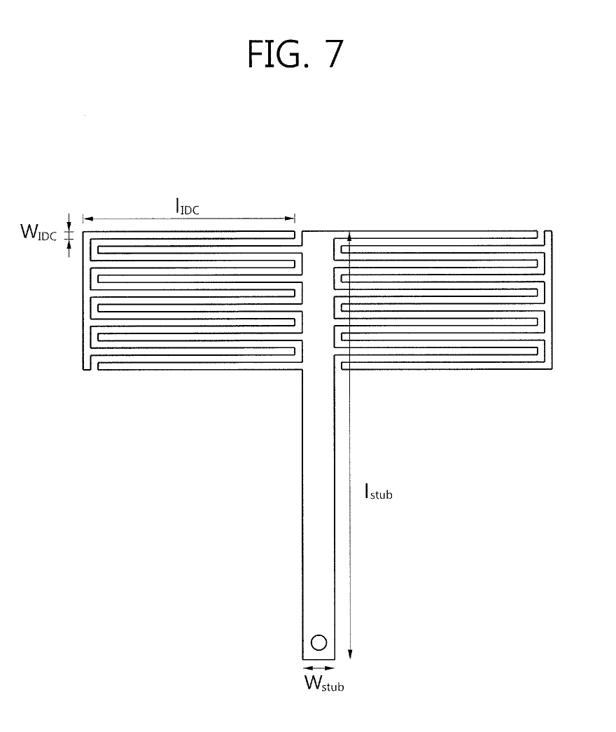

FIG. 6 is a diagram showing a configuration of a CRLH resonator according to an exemplary embodiment of the present invention. FIG. 7 is a diagram showing a physical structure of the CRLH resonator of FIG. 6.

The CRLH resonator 500 is configured by a microstrip line including an input port 501 and an output port 509.

A first interdigital line 502 connected to the input port 501 in series, a second interdigital line 506 connected to an output port 509 in series, a connection line 504 connecting the first interdigital line 502 to the second interdigital line 506, and an inductor line 508 connected to the connection line 504 in parallel and having a shortened end are disposed on the microstrip line.

The first interdigital line 502 and the second interdigital line 506 are configured by a pair of parallel line. The pair of parallel lines faces each other, having a narrow gap disposed therebetween. The parallel lines are connected to a grounded stub and serve as a capacitor having predetermined capacitance.

The connection line 504 includes a serial inductor and a parallel capacitor and in the exemplary embodiment of the present invention, is configured to have a T-junction type and connects the first interdigitial line 502, the second interdigital line 506, and the inductor line 508.

The end of the inductor line 508 is shortened through a shortened circuit 510.

When the connection line 504 is the elements of the right-handed propagation rule generating the phase delay phenomenon, the first interdigital line 502, the second interdigital line 506, and the inductor line 508 are the elements of the left-handed propagation rule generating the phase lead. When a total phase of the phase delay and the phase lead is 0 while summing the elements of the right-handed propagation rule and the left-handed propagation rule, resonance is generated regardless of the wavelength.

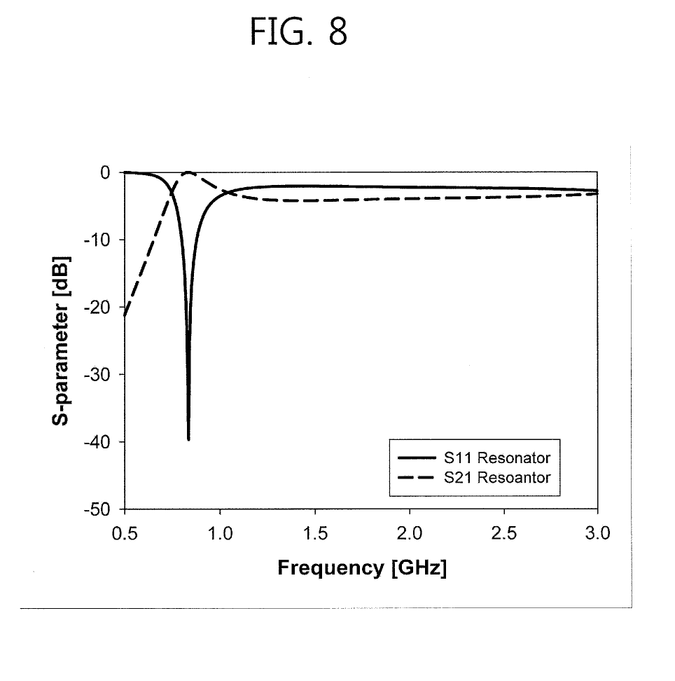

FIG. 8 is a graph showing simulation results for a frequency response of the resonator of FIG. 6. The resonance characteristics are shown in the UHF band of 900 MHz.

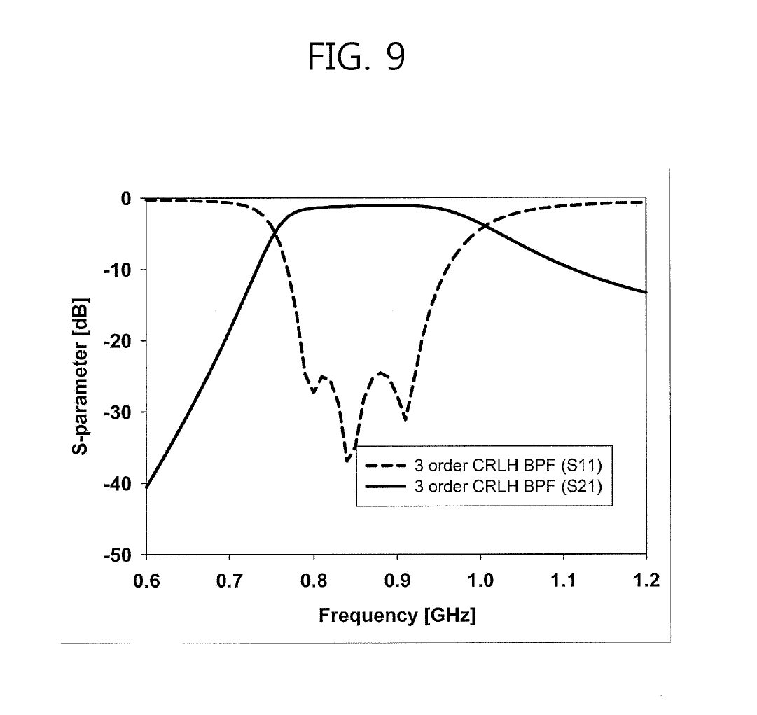

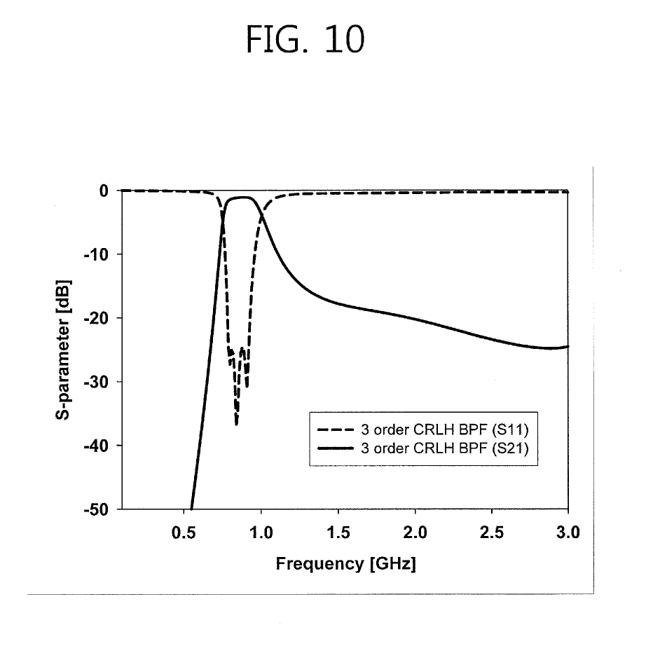

FIG. 9 is a graph showing narrowband frequency response characteristics of the proposed bandpass filter. FIG. 10 is a graph showing broadband frequency response characteristics of the proposed bandpass filter. The bandwidth, the insertion loss, and the return loss are satisfied well in the passband. In addition, the barrier region is wide enough to suppress 3rd order harmonic.

The skirt characteristics (attenuation at edge+10 offset is 20 dB) of the desired targeted high passband may be achieved by increasing an order.

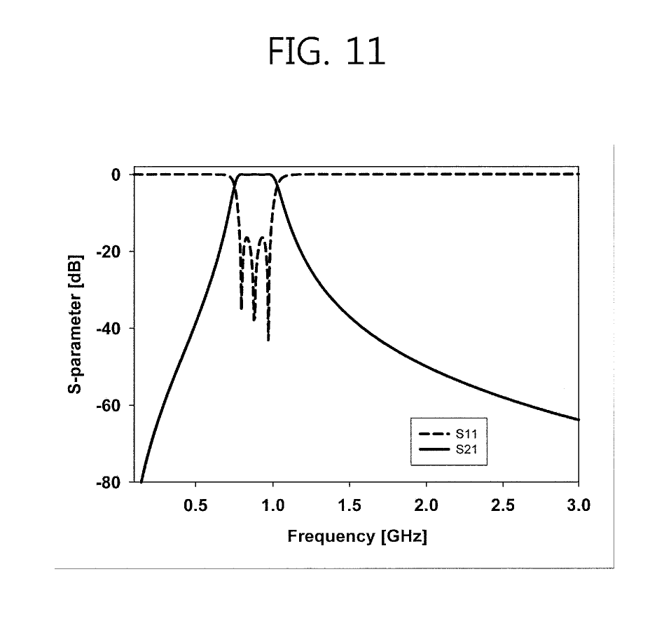

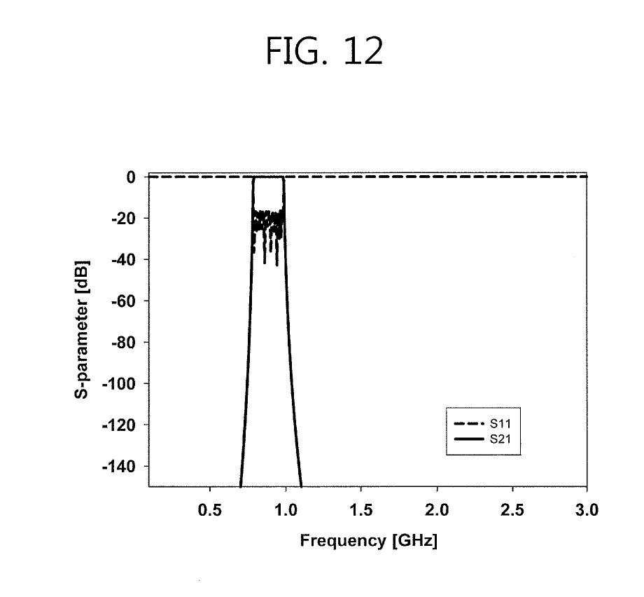

FIG. 11 is a graph showing narrowband frequency response characteristics of the existing bandpass filter. FIG. 12 is a graph showing broadband frequency response characteristics of the existing bandpass filter. As the existing bandpass filter, a well known Chebyshev type 3rd order bandpass filter is used. Since the skirt characteristics are poor, the results of FIG. 12 increase an order to 15 orders.

However, even though the order is not increased to 15 orders, the proposed bandpass filter generates the transmission zero in the coupling structure of the CRLH resonator, thereby greatly improving the skirt characteristics.

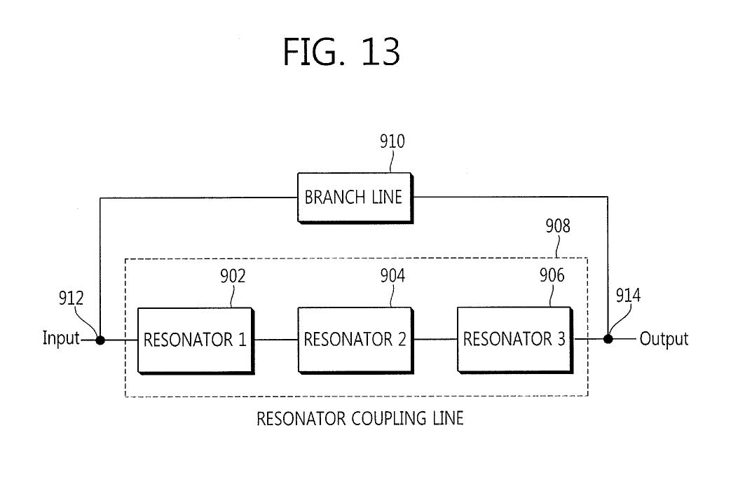

FIG. 13 is a diagram showing a configuration of the bandpass filter according to the exemplary embodiment of the present invention.

The bandpass filter includes resonator coupling lines 908 including three resonators 902, 904, and 906 and a branch line 910. The resonators 902, 904, and 906 are the CRLH resonators and inductively coupled with each other. An example of the CRLH resonator is shown in the embodiment of FIG. 6.

The resonator coupling line 908 is connected to the branch line 910 in parallel. The branch line 910 generates the transmission zero around the passband to improve the skirt characteristics of the passband.

A branch point of the resonator coupling line 908 and the branch line 910 may be disposed with a control unit (not shown) for impedance matching between both lines 908 and 912. When impedance matching is performed between both lines 908 and 912, a flow of a signal flowing into both lines 908 and 910 is good. In addition, the impedance matching is made so that the phase difference between the signals passing through both lines 908 and 912 at the coupling point 914 of both lines 908 and 912 is 180°, thereby forming the transmission zero.

When the transmission zero is formed, the skirt characteristics are improved.

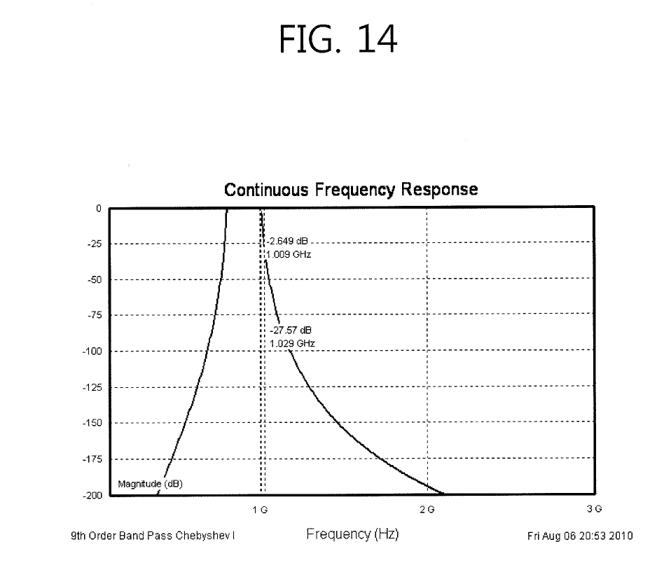

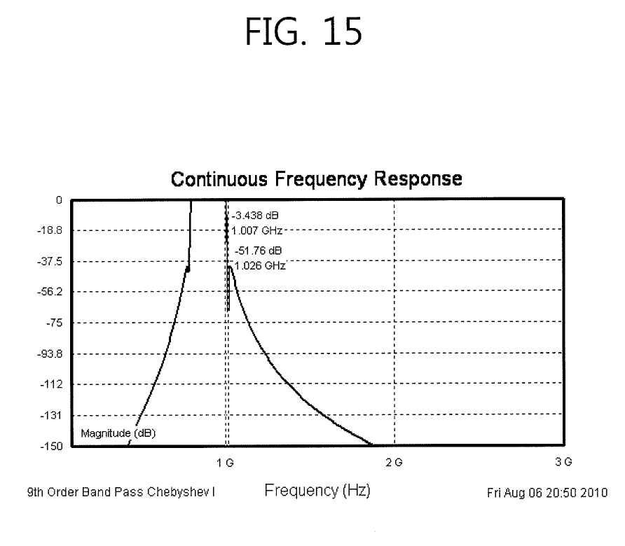

FIG. 14 is a graph showing a frequency response of the existing Chebyshev 9th order bandpass filter. FIG. 15 is a graph showing a frequency response when a transmission zero point is present in the existing Chebyshev 9th order bandpass filter. According to FIG. 14, the skirt characteristics of the attenuation of 10 dB are shown in the passband. Comparing therewith, it can be appreciated from FIG. 15 that the transmission zero is formed around the passband to satisfy the skirt characteristics of the attenuation of about 25 dB.

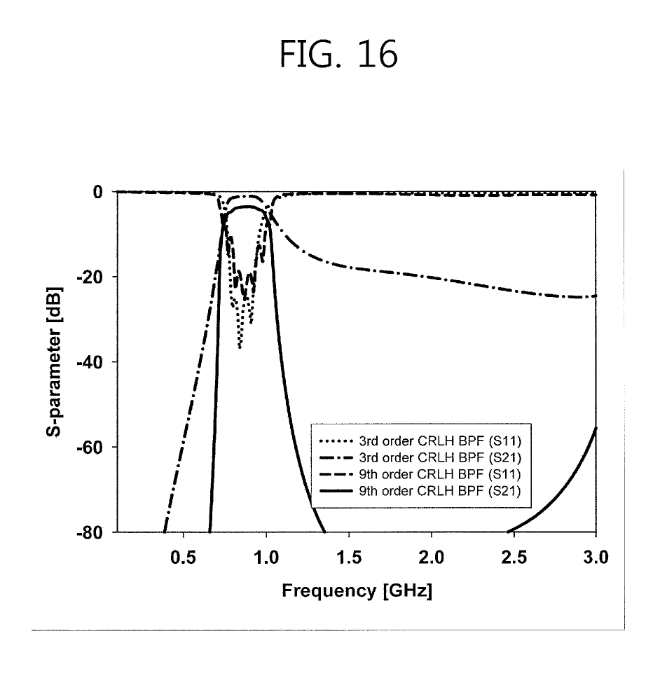

FIG. 16 is a graph showing the frequency response of the proposed bandpass filter. Comparing with the skirt characteristics for the frequency response of the 3rd order bandpass filter of FIG. 10, it can be appreciated that the skirt characteristics are improved. In addition, the 9th order bandpass filter shows better skirt characteristics than the 3rd order bandpass filter.

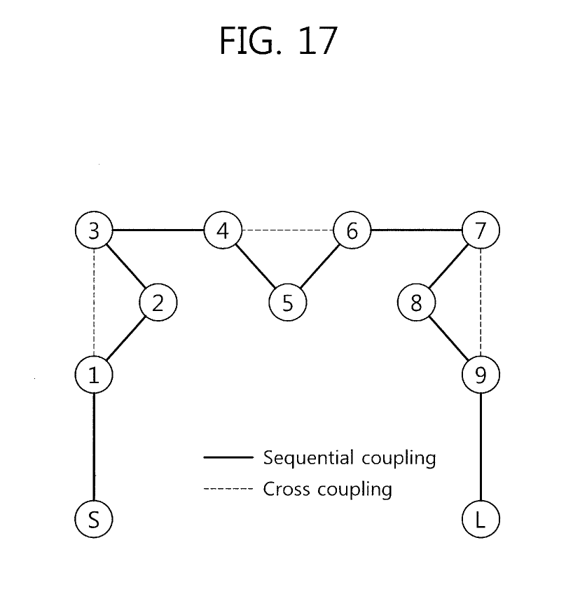

FIG. 17 is a conceptual diagram showing a coupling between resonators of the proposed bandpass filter. Each number shows an index of each resonator.

The resonators from No. 1 to No. 9 are designed as a metamaterial structure based transmission line and shows a non-adjacent resonator coupling structure having excellent frequency selectivity by the transmission zero due to signal cancellation.

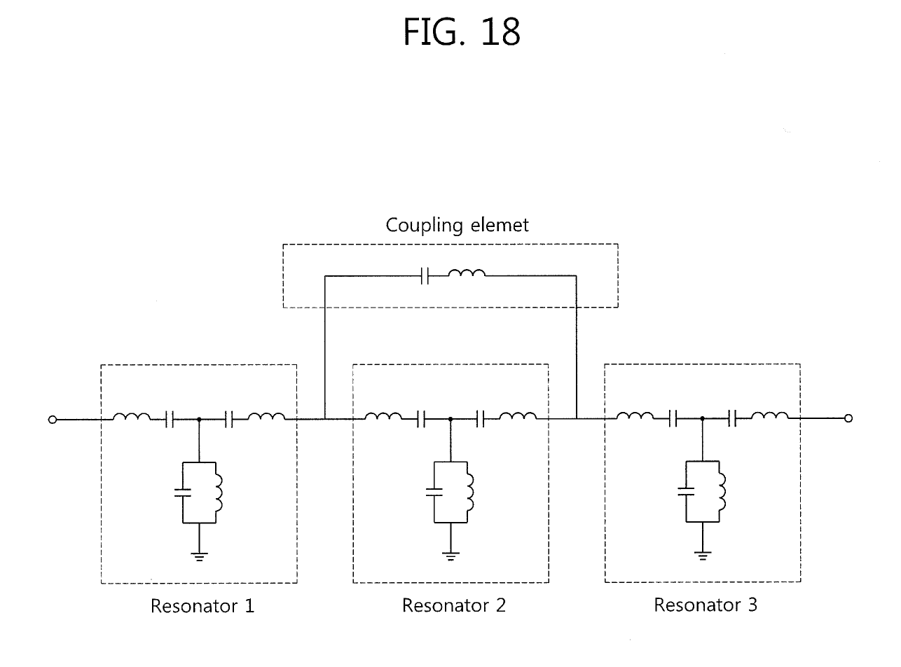

FIG. 18 is an equivalent circuit of the coupling of non-adjacent resonators by a transmission zero point.

Three resonators are inductively coupled with the resonator coupling line. The branch line is connected to the resonator coupling line in parallel and the branch line includes the coupling elements. The phase of the resonator coupling line and the phase of the branch line have a phase difference of 180° and the transmission zero is generated.

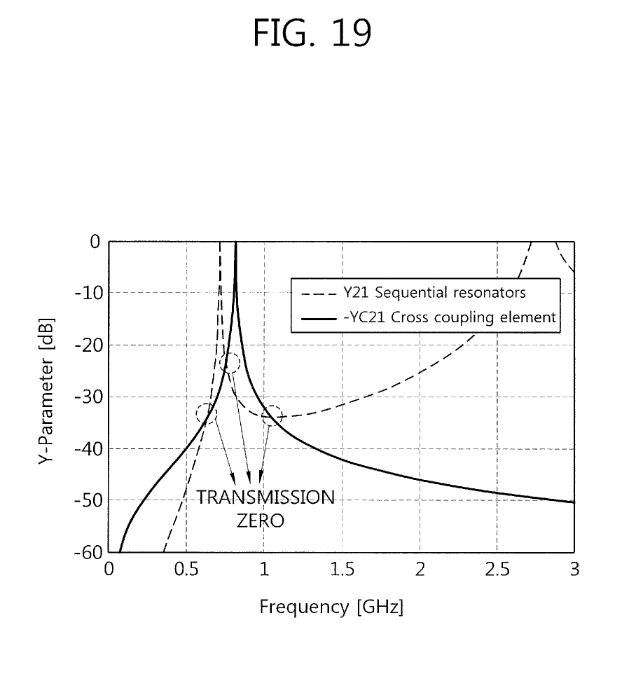

FIG. 19 is a graph showing a frequency that generates the transmission zero point by an admittance parameter. It can be appreciated that the transmission zero is generated at a frequency at which a sum of the admittance of the resonator coupling line and the admittance of the branch line is substantially 0.

In order to generate the transmission zero at the proposed bandpass filter, the phase of the resonator coupling line and the phase of the branch line are opposite to each other. Theoretically, it means that the phase of the resonator coupling line and the phase of the branch line have the difference of 180° from each other. In actually implementing, opposing the phase of the resonator coupling line and the phase of the branch line to each other may have an error of about 180±10°.

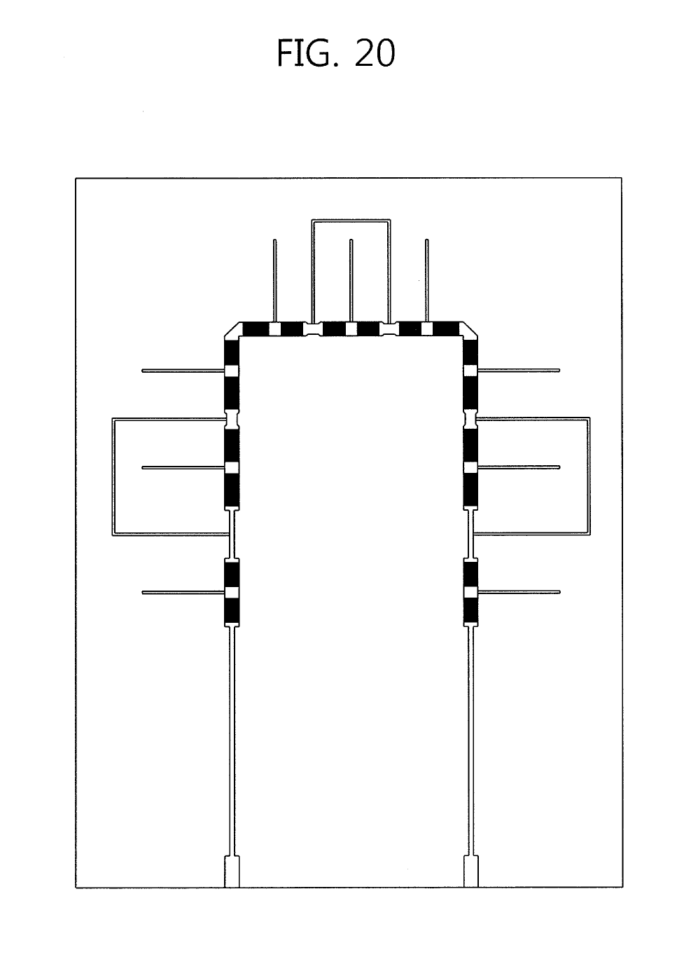

FIG. 20 is a meta material structure based UHF bandpass filter according to an embodiment of the present invention.

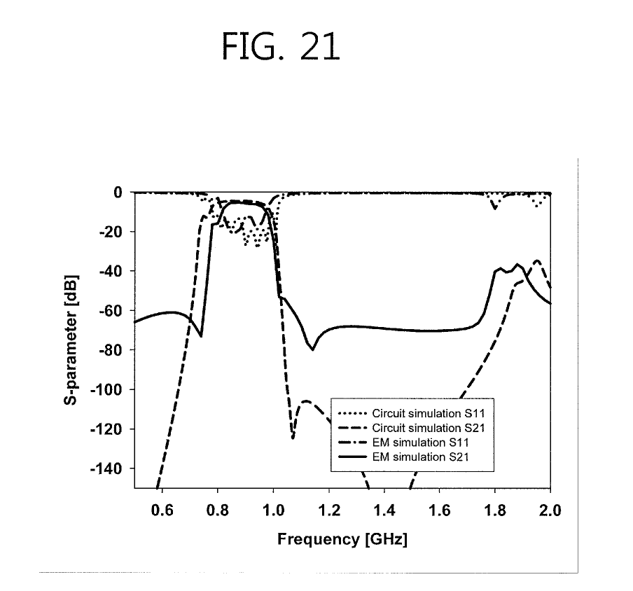

FIG. 21 is a diagram showing three-dimensional electromagnetic simulation results of the bandpass filter according to the exemplary embodiment of the present invention. The skirt characteristics of the passband may be improved and the inter-band isolation may be secured, by implementing the filter generating the transmission zero at the upper side and the lower side of the passband.

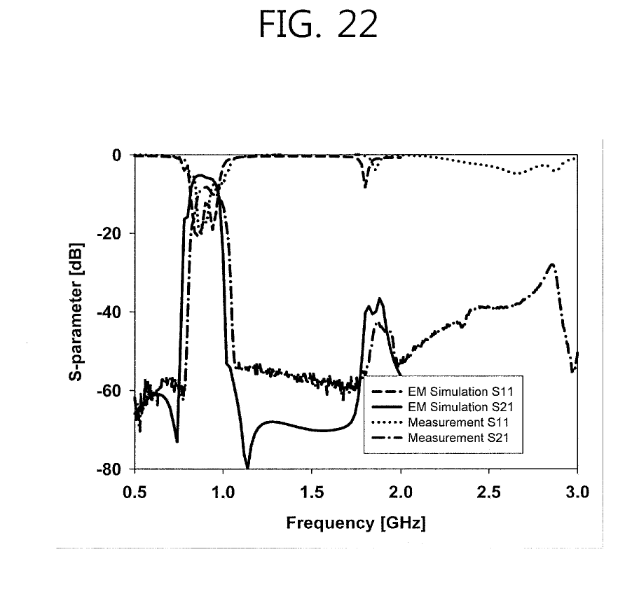

FIG. 22 is a diagram showing three-dimensional electromagnetic simulation results of the bandpass filter according to the exemplary embodiment of the present invention. It can be shown that the transmission zero is generated after the upper side and the lower side of the UHF passband to greatly improve the skirt characteristics.

The microminiaturization of the bandpass filter may be implemented using the inductive coupling of the CRLH resonators. The excellent skirt characteristics may be shown by connecting the branch lines generating the transmission zero to the inductive coupling structure of the CRLH resonators.

The proposed bandpass filter may be included in various electronic devices. The electronic devices may include the electronic devices for wireless communication, the electronic devices for wired communication, or the like. The bandpass filter included in the electronic device may be used to transmit and receive the signal.

What is claimed is:

1. A bandpass filter, comprising:
a resonator coupling line on which a plurality of composite right/left-handed (CRLH) resonators are disposed,
wherein the plurality of CRLH resonators are inductively coupled with each other.

2. The bandpass filter of claim 1, wherein each of the plurality of CRLH resonators includes:
a first interdigital line connected to an input port in series;
a second interdigital line connected to an output port in series;
a connection line connecting the first interdigital line to the second interdigital line; and
an inductor line connected to the connection line in parallel and having a shortened end.

3. The bandpass filter of claim 2, wherein each of the first interdigital line and the second interdigital line includes a pair of parallel lines facing each other, having a gap disposed therebetween.

4. The bandpass filter of claim 3, wherein each of the first interdigital line and the second interdigital line is a capacitor.

5. The bandpass filter of claim 2, wherein the connection line is a T-junction type including a serial inductor and a parallel capacitor.

6. The bandpass filter of claim 2, wherein the connection line is an element of a right-handed propagation rule generating a phase delay and the first interdigital line, the second interdigital line, and the inductor line are elements of a left-handed propagation rule generating a phase lead.

7. The bandpass filter of claim 6, wherein a total phase of the phase delay and the phase lead is substantially 0.

8. The bandpass filter of claim 6, wherein a phase of the element of the right-handed propagation rule and a phase of the element of the left-handed propagation rule are opposite to each other.

9. The bandpass filter of claim 6, wherein the phase of the element of the right-handed propagation rule and the phase of the element of the left-handed propagation rule have a difference of 180°.

10. The bandpass filter of claim 1, wherein the passband of the bandpass filter is an ultra high frequency (UHF) band.
